(19) United States
(12) Patent Application Publication
(10) Pub. No.: US 2010/0018648 A1
(43) Pub. Date: Jan. 28, 2010

(54) WORKPIECE SUPPORT FOR A PLASMA REACTOR WITH CONTROLLED APPORTIONMENT OF RF POWER TO A PROCESS KIT RING

(75) Inventors: KENNETH S. COLLINS, San Jose, CA (US); Douglas A. Buchberger, JR., Livermore, CA (US); Kartik Ramaswamy, San Jose, CA (US); Shahid Rauf, Pleasanton, CA (US); Hiroji Hanawa, Sunnyvale, CA (US); Jennifer Y. Sun, Mountain View, CA (US); Andrew Nguyen, San Jose, CA (US); Thorsten B. Lill, Santa Clara, CA (US); Meihua Shen, Fremont, CA (US)

Correspondence Address: LAW OFFICE OF ROBERT M. WALLACE, 2112 EASTMAN AVENUE, SUITE 102, VENTURA, CA, 93003, US

(73) Assignee: Applied Marterials, Inc., Santa Clara, CA (US)

(21) Appl. No.: 12/178,032

(22) Filed: Jul. 23, 2008

(51) Int. Cl. H01L 21/3065

(52) U.S. Cl. 156/345.24

(57) ABSTRACT

In an electrostatic chuck, RF bias power is separately applied to a workpiece and to a process kit collar surrounding the workpiece. At least one variable impedance element governed by a system controller adjusts the apportionment of RF bias power between the workpiece and the process kit collar, allowing dynamic adjustment of the plasma sheath electric field at the extreme edge of the workpiece, for optimum electric field uniformity under varying plasma conditions, for example.

### BACKGROUND

In plasma processing of a workpiece such as a semiconductor wafer, uniformity requirements have extended to within 5 mm or 3 mm of the workpiece edge, and lately, are being extended to within 2 mm or even 1 mm of the edge. The workpiece is typically electrostatically clamped to a workpiece support comprising an electrostatic chuck (ESC), which is used to perform several functions such as coupling RF bias power, voltage or current to the plasma via the workpiece and/or providing a ground return path for RF current coupled to the plasma from a different electrode. The ESC is also typically used to heat or cool the workpiece or control the workpiece temperature. For etch processes, the ESC is typically smaller in size than the workpiece so as to cover and protect the ESC from the plasma. Otherwise, the plasma can damage or erode the ESC, and can contaminate the workpiece or chamber by material sputtered or etched from the ESC. The workpiece edge typically is not flat, and instead includes a bevel or radius, preventing effective contact between the workpiece support and the workpiece, particularly at the workpiece edge. The causes some difficulties in extending uniform processing across the workpiece to the edge. Even with a perfectly conducting workpiece, a plasma sheath that forms over the biased or unbiased workpiece, or the plasma sheath electric field, is not uniform due to the finite electrode dimension, because the electric field across the workpiece changes near the edge region as compared with the electric field over the rest of the workpiece. Because the workpiece or wafer is not a perfect conductor, there may be some additional electric field variation near the edge. The result is that the plasma ion flux and ion energy or ion angular energy distribution may be different at the workpiece edge as compared with the rest of the workpiece. Even the plasma radical flux to the workpiece edge may differ as well from radical flux to the rest of the workpiece. In plasma etch processes, such edge effects produce non-uniform processing results at the wafer edge that can manifest as tilting or twisting of etch profiles of high aspect ratio openings near the wafer edge, for example. Other plasma process parameters may differ sharply at the wafer edge, including critical dimension (CD) bias, etch rate, sputtering, deposition rate, etch selectivity, etch microloading, and so forth.

Conventional methods of reducing the edge effect may include (1) a conducting, semiconducting or dielectric peripheral element (for example a ring or collar in the case where the workpiece is a round semiconductor wafer); or (2) an edge temperature zone that allows controlling the workpiece edge to a different temperature than the rest of the workpiece; or (3) an edge gas introduction zone that allows a different gas mixture or different gas mixture ratio to the edge region; or (4) a plasma confinement ring near the workpiece edge that reduces the rate of by-product removal from the workpiece edge or increases the recombination rate of plasma species near the workpiece edge; or (5) an edge peripheral element that is temperature controlled to a temperature selected to change the local plasma conditions, such as to enhance or decrease plasma species in the vicinity of the edge (such as depleting certain species by causing deposition to occur, depleting certain species by causing etching of the peripheral element, or increasing certain species by etching peripheral element to form by-product species. Methods (2), (3), (4) and (5) do not directly address the problem of non-uniform sheath electric field, but use other techniques to change the edge processing. While method (1) directly addresses the problem, it does not permit control over the workpiece edge sheath electric field as different plasma conditions are selected, so is at best a compromise for a wide range of plasma conditions. What is needed is a method to control workpiece edge plasma sheath conditions such as ion energy, ion angular energy distribution or ion density or flux (thus to control, for example, workpiece structure parameters such as CD uniformity (critical dimension), profile (slope), etch rate (or selectivity) that is controllable as different plasma conditions are selected, as chamber conditions change or as different workpiece structures and processed.

### SUMMARY

An RF bias workpiece support system is provided for use in a plasma reactor chamber. A dielectric puck has a workpiece support surface for supporting a workpiece. A workpiece electrode is embedded in the puck. The workpiece electrode underlies and is generally parallel to the workpiece support surface. A metal plate underlies the dielectric puck. An annular process kit collar surrounds a peripheral edge of the workpiece support surface. A process kit electrode element underlies the process kit collar. An RF plasma bias power supply is coupled to the workpiece electrode and to the process kit electrode element. Control of RF bias power splitting between the workpiece and the process kit collar is performed by a variable RF impedance element coupled between the RF plasma power supply and one of: (a) the workpiece electrode, (b) the process kit electrode. The variable RF impedance element comprises a reactive element having a variable reactance. A system controller is connected to a control input of the variable RF impedance element whereby to govern the variable reactance of the reactive element of the variable RF impedance element.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1A depicts plasma reactor including a workpiece support pedestal in accordance with a first embodiment.

FIG. 1B is an enlarged view of a portion of FIG. 1A depicting certain details associated with the wafer support pedestal.

FIG. 2 depicts a workpiece support pedestal in accordance with a second embodiment.

FIG. 3 depicts a workpiece support pedestal in accordance with a third embodiment.

FIG. 4 depicts a workpiece support pedestal in accordance with a fourth embodiment.

FIG. 5 depicts a modification of the embodiment of FIG. 1B in which features for thermally controlling a process kit collar are included.

FIG. 6 is a simplified schematic diagram of a circuit that can be employed as one of the variable impedance elements used to apportion RF power between the process kit and the workpiece in the embodiments of FIGS. 1-4.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention include an electrostatic chuck, in which RF bias power is separately coupled to a workpiece and to a process kit collar surrounding the workpiece. At least one variable impedance element governed by a system controller adjusts the apportionment of RF bias power between the workpiece and the process kit collar, allowing dynamic adjustment of the plasma sheath electric field at the extreme edge of the workpiece, for optimum electric field uniformity under varying plasma conditions, for example.

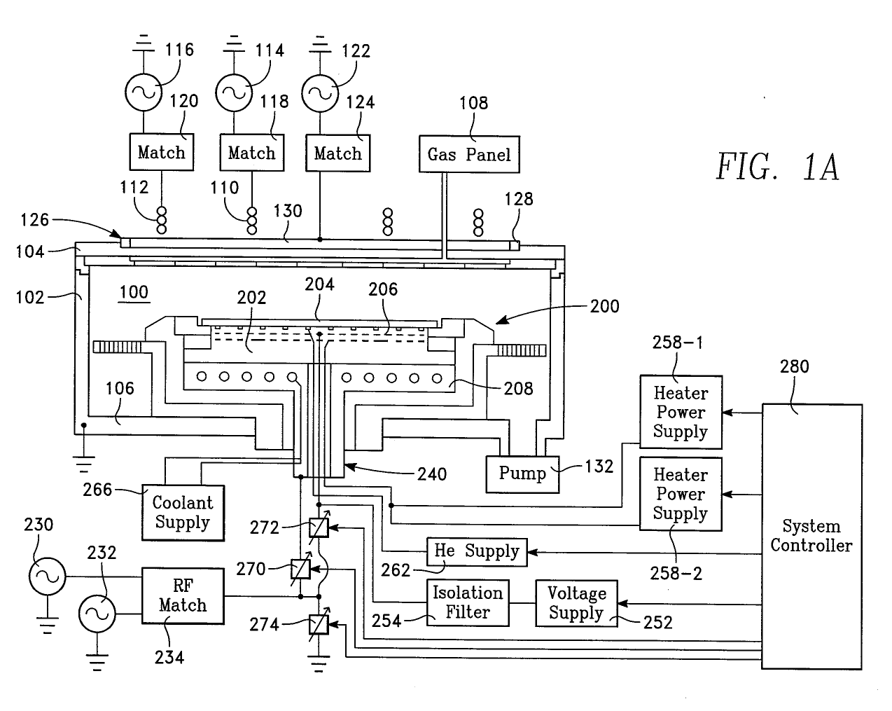

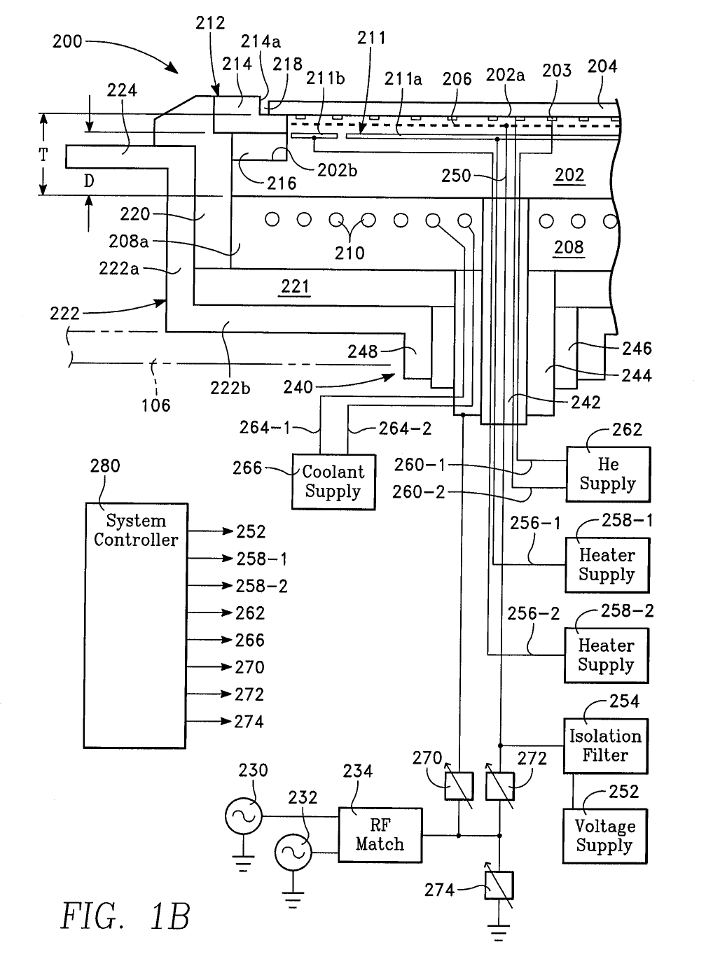

Referring to FIGS. 1A and 1B, a plasma reactor has a chamber 100 defined by a cylindrical sidewall 102, a ceiling 104 and a floor 106 whose peripheral edge meets the sidewall 102. The ceiling 104 may be a gas distribution plate that received process gas from a process gas supply 108. The sidewall 102 and floor 106 may be formed of metal and connected to ground. A vacuum pump 132 evacuates the chamber 100 through a port in the floor 106. Plasma RF source power may be inductively coupled into the chamber 100 from respective inner and outer coil antennas 110, 112 that are connected to respective RF source power generators 114, 116 through respective RF impedance match elements 118, 120. The ceiling or gas distribution plate 104 may be formed of a non-conductive material in order to permit inductive coupling of RF power from the coil antennas 110, 112 through the ceiling 104 and into the chamber 100.

Alternatively, or in addition, RF plasma source power from a VHF generator 122 and impedance match 124 may be capacitively coupled into the chamber 100 from an overhead electrode 126. In one embodiment, the overhead electrode 126 may be separate from the ceiling gas distribution plate 104.

In one embodiment, RF power may be inductively coupled into the chamber 100 from the coil antennas 110, 112 through gas distribution plate 104 and through the overhead electrode 126. In this embodiment, the gas distribution plate may be formed of a dielectric or semiconductive material while the overhead electrode 126 may be in the form of a Faraday shield having an outer ring conductor 128 and plural conductive fingers 130 extending radially inwardly from the outer ring conductive 128. The Faraday shield 126 may be connected to ground to provide a ground return for RF power coupled to a wafer support pedestal to be described below. The Faraday shield 126 may be grounded with respect to a selected frequency through an RF filter.

In the absence of the coil antennas 110, 112, the ceiling gas distribution plate 104 may be formed completely of metal and serve as the overhead electrode 126, being coupled to the VHF generator 122 through the impedance match 124.

A workpiece support pedestal 200 is provided inside the chamber 100 for holding a workpiece 204, such as a semiconductor wafer, mask, photomask, display panel, solar panel element, or the like. The pedestal 200 may be an electrostatic chuck (ESC) that electrostatically clamps or chucks the workpiece 204, and includes a dielectric top layer or puck 202 having a top surface 202a for supporting the workpiece 204. A conductive grid 206 is embedded within the puck 202 within a small distance (e.g., 0.25 mm to 2 mm) of the puck top surface 202a. The grid 206 serves as the ESC electrode to which a D.C. chucking voltage is applied in a manner described below. The puck 202 is supported on a metal plate or cathode 208 to which RF plasma bias power may be applied. The puck 202 may be formed of an insulating material (e.g., having a resistivity greater than 10¹² Ohm·cm) or of a semiconducting material (e.g., having a resistivity between 10⁸ Ohm·cm and 10¹² Ohm·cm).

Various features are provided for thermal control. An array of channels 203 are formed in the puck top surface 202a for supply of a thermally conductive gas (e.g., helium) to control thermal conductance between the workpiece 204 and the puck 202. These channels are completely enclosed whenever the workpiece 204 is clamped onto the puck top surface 202a. The cathode 208 contains internal fluid flow passages 210 through which a liquid coolant may be circulated. An electric-heater 211 may be embedded within the puck 202. The heater 211 may be divided between separately controlled inner and outer heaters 211a and 211b, respectively.

A process kit ring assembly 212 surrounds the edge of the puck 202 and may include a process kit collar 214 overlying a process kit spacer ring 216 that rests in an annular shoulder 202b of the puck 202. A shoulder 214a of the collar 214 surrounds the edge of the wafer 204, leaving a small radial gap 218. An annular process kit insulator 220 surrounds the ring assembly 212, the puck 202 and the cathode 208. A disk-shaped cathode insulator 221 extending from the bottom edge of the annular insulator 220 underlies the cathode 208. An optional ground housing 222 has an outer annular portion 222a surrounding the annular insulator 220 and a disk shaped portion 222b underlying the cathode insulator 221. An optional annular ground baffle 224 extends from the annular portion 222a of the ground housing 222 to the chamber side wall 102.

RF bias power generators 230, 232 apply RF bias power to the cathode 208 through an RF bias impedance match circuit 234. The generator 230 may have an HF frequency (e.g., below 27 MHz) or VHF frequency (e.g., greater than 27 MHz) while the generator 232 may have an MF or LF frequency (e.g., below 4 MHz). The impedance match circuit 234 may be connected to the cathode 208 by a coaxial conductor assembly 240 extending from the cathode 208 through the chamber floor 106. The coaxial conductor assembly 240 has a center insulator 242, a hollow cylindrical cathode feed conductor 244 surrounding the center insulator 242 and a hollow cylindrical cathode feed insulator 246 surrounding the cathode feed conductor 244 and merging with the disk-shaped cathode insulator 221. The cylindrical cathode feed insulator 246 may be surrounded by an annular cathode ground return conductor 248 that extends from the cathode ground housing 222.

Utilities are coupled into the pedestal 200 by various conductors and conduits extending through the coaxial feed assembly 240. A grid feed conductor 250 extends through the center insulator 242 to the grid 206. An ESC voltage supply 252 furnishes a D.C. voltage to the grid 206 through the grid feed conductor 250. An RF isolation filter 254 presents a high impedance to the RF voltage on the grid feed conductor and prevents RF power from reaching the D.C. supply. Heater supply conductor pairs 256-1, 256-2 extend through the center insulator 242 to the inner and outer heaters 211a, 211b. Independent AC power supplies 258-1, 258-2 are coupled to the heaters 211a, 211b through the respective heater supply conductor pairs 256-1, 256-2. Gas feed conduits 260-1, 260-2 extend through the center insulator 242 to input and output ends (not shown) of the array of channels 203 in the puck surface 202a. A supply 262 of a thermally conductive gas (e.g., helium) is coupled to the gas feed conduits 260-1, 260-2. Coolant feed conduits 264-1, 264-2 extend through the cylindrical cathode feed conductor 244 to input and output ports (not shown) of the coolant channels 210 in the cathode 208. A supply 266 of a liquid coolant is coupled to the coolant feed conduits 264-1, 264-2 for recirculation of a liquid coolant through the coolant channels 210. The coolant may be cooled or heated by an external heat exchanger.

The cathode 208 is coupled to the output of the bias RF impedance match circuit 234 via the cathode RF feed conductor 244 through an optional cathode bias variable RF impedance element 270. The grid feed conductor 250, in addition to being coupled to the ESC voltage supply 252, is coupled to the output of the bias RF impedance match circuit 234 through a grid bias variable RF impedance element 272. In one embodiment, the cathode RF feed conductor 244 and the grid feed conductor 250 are coupled to RF ground through an optional cathode ground variable impedance element 274. In one embodiment, the cathode ground variable impedance element 274 is a band pass filter having a very narrow pass band centered at the frequency of the VHF power generator and blocking the frequencies of the RF bias power generators 230, 232. This feature enables the pedestal 200 to act as an RF ground return electrode for VHF power capacitively coupled into the chamber 100 without shorting the bias power to ground.

A system controller 280 governs the variable impedances of the impedance elements 270, 272, 274, the pressure of the gas supply 262, the fluid temperature and flow rate of the coolant supply 266, the output currents of the AC heater supplies 258-1, 258-2 and the D.C. output voltage of the ESC supply 252.

In the illustrated embodiment of FIGS. 1A and 1B, the entire grid 206 underlies the wafer 204, none of it underlying the process kit collar 214, so that any RF bias power applied to the grid 206 is capacitively coupled to the wafer 204, with comparatively little or no capacitive coupling to the process kit collar 214. An annular peripheral portion 208a of the cathode 208 extends beneath the process kit collar 214, so that a portion of RF bias power applied to the cathode is capacitively coupled to the process kit collar 214. This structure enables the RF bias power (or voltage or current) on the process kit collar 214 may be adjusted relative to the RF bias power (or current or voltage) on the wafer 204 by applying different amounts of RF bias power to the grid 206 and the cathode 208.

The cathode and grid variable RF impedance elements 270, 272 determine the apportionment of RF bias power (or current or voltage) between the cathode 208 and the grid 206. For this purpose, only one of the two variable impedance elements 270, 272 is required (although the combination of both of them enhances the adjustment range). For example, if the cathode variable impedance element 270 is replaced by a direct electrical connection from the match circuit 234 to the cathode feed conductor 244, then the impedance of the grid variable impedance element 272 by itself determines the apportionment of RF power between the cathode 208 and the grid 206. This changes the apportionment of RF bias power between the wafer 204 and the process kit collar 214. This is because, as described in the foregoing paragraph, the outer annulus 208a of the cathode 208 directly underlies the process kit collar 214, and capacitively couples RF bias power to the process kit collar 214, while the grid 206 underlies the wafer 204 and does not underlie the process kit collar 214, and capacitively couples nearly all of its RF bias power to the wafer 204, not the process kit collar 214. When the grid variable impedance element 272 increases or decreases the proportion of RF power applied to the cathode, the RF power coupled to the process kit collar is increased or decreased, respectively, relative to the power coupled to the wafer 204. How this apportionment of RF power operates will now be described.

The thickness T of the puck 202 and the distance D from the cathode 208 to the process kit collar 214 are selected to “over-compensate” the bias power density (or voltage or current) coupled to the plasma over the process-kit collar relative to the bias power density coupled to the plasma over the central portion of the wafer 204. This is done by designing the capacitance per unit area between the process kit collar 214 and the cathode 208 to be greater than the capacitance per unit area between the wafer 204 and the cathode 208. If the process kit collar 214 is coupled to a larger plasma area than the RF coupled area between the cathode 208 and the collar 214, or if the collar 214 is loaded by additional capacitance to ground (for example in the radial outward direction), then the capacitance per unit area between process kit collar 214 and the cathode 208 may need to be even larger yet with respect to the capacitance per unit area between wafer 204 and the cathode 208 to achieve the desired over-compensation.

The thickness of the collar 214 can be selected to be “small” to keep cost of this consumable element low, typically about 1-4 mm. The thermal resistance of the ESC puck 202 increases with thickness, as does its cost, so the total thickness of the puck 202 is typically less than about 25 mm for a high thermal conductivity material such as aluminum nitride, or about 10 mm for a low thermal conductivity material such as aluminum oxide or yttrium oxide. For example, if the total ESC puck thickness is selected to be 7 mm, a 2 mm thick process kit dollar (214) of quartz, silicon or silicon carbide is selected. If semiconductor material (such as SiC or Si) is selected, then the collar 214 may extend the effective area of the pedestal electrode beyond even the area of the cathode base 208. In some cases, the collar 214 may be Si or SiC while the spacer 216 may be a material such as quartz when the reactor is employed to etch a Si-containing material. Besides extending the electrode effective area beyond the diameter of the cathode 208, the etch by-products may be more similar to those by-products from the wafer being etched, thereby promoting etch uniformity to the edge by minimizing the local by-product change at wafer edge. Other materials with a lower dielectric constant such as quartz may be used for collar material, although the electrode effective area may be extended less beyond the cathode diameter than with a high dielectric constant material or a semiconductor. High dielectric constant material such as yttrium oxide may be used for the spacer 216, for example, or for the collar 214.

The RF grid bias variable impedance element 272 is recipe selectable via the system controller 280. In the case where a vacuum variable capacitor is used as the main element of the grid variable RF impedance element 272, a low minimum capacitance value diverts a minimum of RF current from the cathode 208 to the grid 206. The process kit collar 214 in this case is still over-compensated relative to the apportionment of RF bias power (as discussed above). The RF grid bias variable impedance element 272 may be selected to a higher capacitance value to allow some current to bypass the relatively low capacitance of the pedestal structure between the cathode 208 and the wafer 204. This decreases the over-compensation of the RF power coupled to the plasma via the process kit collar 214. A sufficiently high capacitance value in the grid variable impedance element 272 may be selected so that the effective capacitance per unit area between the process kit collar 214 and the cathode 208 is less than the effective capacitance per unit area between the wafer 204 and the cathode 208 (taken in parallel with the selected capacitance of the variable impedance element and weighted by the same area). In such a case, the process kit power coupling will be under-compensated.

While the selection of different capacitance values of the RF grid bias variable impedance element 272 substantially changes the voltage on the cathode base and the driving point input impedance of the cathode transmission line presented to the RF bias match 234, the bias RF impedance match circuit 234 compensates by changing the reactance of one of its internal elements (e.g., a series element), providing for substantially constant power coupled to the plasma. Thus, although variation of the capacitance of the grid variable impedance element 272 changes the power density (or voltage distribution or current density) apportionment between the plasma region adjacent the process kit collar 214 versus the plasma region adjacent the wafer 204, the net power over the two regions remains substantially constant.

The adjustment or apportionment of relative bias RF power density (or voltage density or current density) between the wafer and process kit regions (e.g., the over-compensation or under-compensation discussed above) may be used to tune wafer structure or feature CD, profile angle (tilt), or etch rate, or etch selectivity to meet specific requirements. It may also be used to compensate for non-uniformities of plasma parameters (such as ion energy, ion angular energy distribution or ion density or flux) arising from inductively or capacitively coupled plasma source power, effects of D.C. magnetic confinement and so forth). Specifically, in the extreme edge region of the wafer, the tilting of the RF electric field lines at the wafer surface can be altered or corrected to avoid degradation of etch profile results, as manifested in etch profile tapering and etch profile twisting at the wafer edge.

In a related approach, the material of the process kit collar 214 is selected to affect the chemical species content of the plasma near the wafer edge. For example, the collar material may react with the plasma to consume certain targeted species to improve process performance near the wafer edge. Or, the collar material may react with the plasma to generate more of a desired species near the wafer edge to improve process performance. The controller 280 may vary the RF bias power on the process kit collar 214 to control the participation rate of the collar 214 with plasma, to obtain different participation rates as required for different process recipes or different phases of the same process recipe.

In a converse approach, the participation rate of the collar 214 is controlled by regulating the temperature of the collar, while apportionment of RF bias power to the collar 214 is selected by the controller 280 to make the plasma bias sheath electric field at the workpiece edge more uniform (i.e., conform with the sheath electric field over the main portion of the workpiece) for a given set of process conditions. This eliminates or minimizes non-uniformities at the wafer edge, thereby obtaining better uniformity of ion velocity angular distribution (or other plasma performance parameters) across the wafer surface up to and beyond the wafer edge. The controller 280 may be used to preserve electric field uniformity by adjusting the RF bias power coupled to the collar 214 as different process conditions arise, such as changes in bias RF power level, source RF power level, D.C. magnetic field levels, and process gas composition, for example.

The adjustment or apportionment by the controller 280 of the RF bias power coupled to the process kit collar 214 may also be used to enhance or reduce plasma reaction with the process kit collar for cleaning or surface conditioning of process kit collar 214.

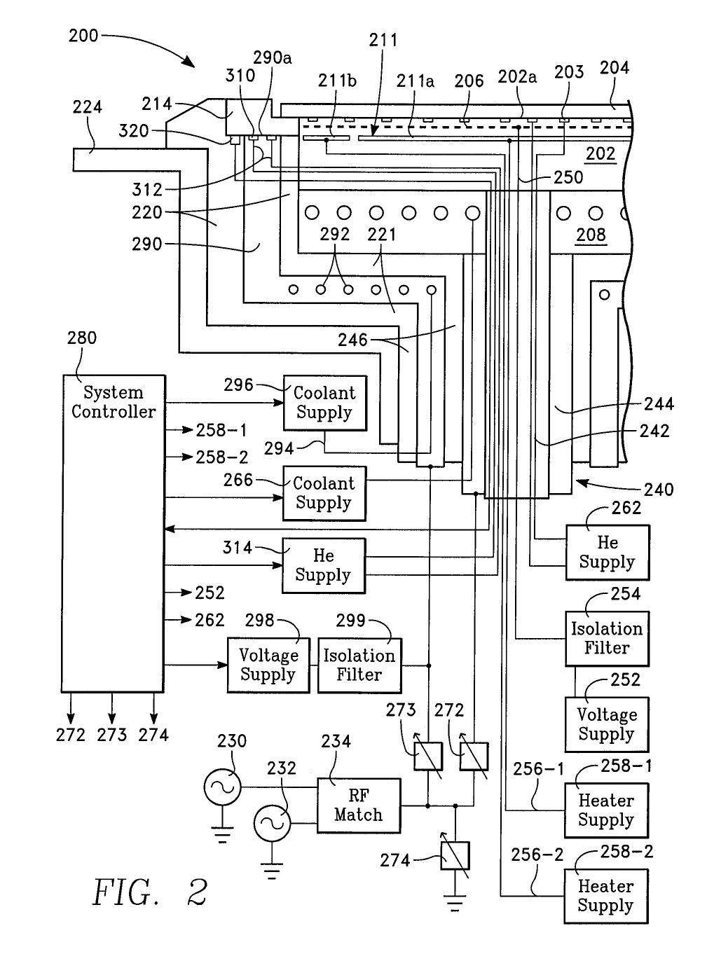

FIG. 2 illustrates a modification of the embodiment of FIGS. 1A and 1B in which a cylindrical process kit electrode 290 extends axially upward through the cathode feed insulator 246, disk-shaped cathode insulator 221 and the cylindrical process kit insulator 220. The process kit electrode 290 provides RF electrical coupling to the process kit collar 214. In the implementation of FIG. 2, the optional process kit ring 216 has been eliminated, although it may optionally be included in the embodiment of FIG. 2. In the embodiment of FIG. 2, the output of the bias RF match 234 is not connected to the grid feed conductor 250. Instead, the output of the bias RF match is coupled to the bottom end of the process kit electrode 290, as well as being coupled to the cathode feed conductor 244 through the grid variable RF impedance element 272. An optional process kit variable impedance element 273 operated by the controller 280 may be interposed between the output of the bias RF match 234 and the process kit electrode 290. Only one of the two variable impedance elements 272, 273 of FIG. 2 are required. The presence of either one of the variable impedance elements 272, 273 enables the controller 280 to control apportionment of RF bias power between the process kit (via the electrode 290) and the wafer (via the cathode 208). This apportionment operates in a manner similar to that described above with reference to the embodiment of FIGS. 1A and 1B.

As mentioned above in this specification, the apportionment of RF power to the process kit collar 214 may be used to optimize uniformity of the electric field across the wafer surface up to and beyond the wafer edge, while the participation rate of the selected material of the collar 214 is controlled independently by controlling the temperature of the collar 214. Independent temperature control of the process kit collar 214 may be realized by providing a set of separate internal coolant passages 292 within the process kit electrode 290. A set of coolant conduits 294 extending axially through the process kit electrode 290 couples the internal coolant passages 292 with a process kit coolant supply 296. The process kit collar 214 may be electrostatically clamped in place by applying a D.C. chucking voltage to the process kit electrode 290 from a process kit ESC voltage supply 298. An optional RF isolation filter 299 blocks RF current from reaching the ESC supply 298. Fine control of the process kit collar temperature may be realized by varying the output voltage of the process kit ESC supply 298, under control of the system controller 280. By varying the ESC clamping force between the process kit collar 214 and the cooled electrode 290, the thermal conductivity between them is varied and may be precisely controlled by the controller 280 for fine control of the temperature of the process kit collar 214. Alternatively, or in addition, thermal control of the process kit collar 214 may be facilitated by providing gas channels 310 in the top surface 290a of the process kit electrode 290 underlying the collar 214. Gas conduits 312 extending through the process kit electrode 290 provide for supply of a thermally conductive gas (e.g., helium) furnished from a gas supply 314. The gas pressure of the gas supply 314 is controlled by the system controller 280. The pressure within the channels 310 affects the electrode-to-collar thermal conductivity and hence affects the temperature of the collar 214. A temperature sensor 320 may be provided in a top surface of the process kit insulator 220 and contact the process kit collar 214. The output of the temperature sensor 320 may be coupled to an input of the system controller 280, so that the system controller 280 can provide rapid precise closed loop temperature control of the process kit collar 214. Such closed loop temperature control can move the collar 214 to different target temperatures required during different phases of a given process recipe, for example.

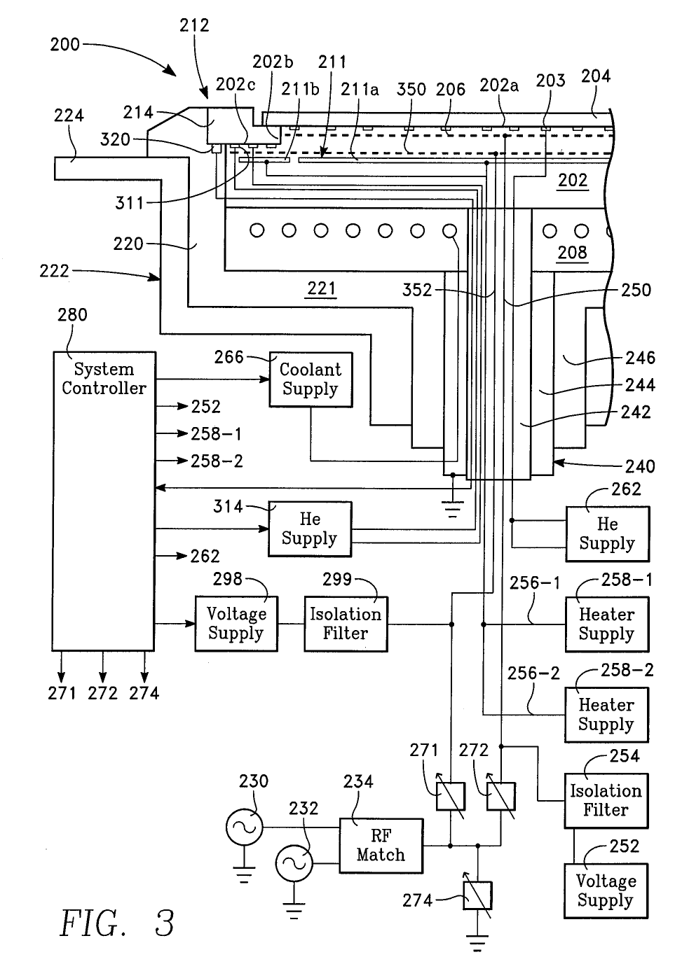

FIG. 3 depicts another modification of the embodiment of FIGS. 1A and 1B, in which the cathode or metal plate 208 is grounded, rather than being driven by RF bias power. Instead, RF bias power is applied to a process kit grid 350 underlying the process kit 212 and embedded inside the puck 202. The process kit grid 350 is placed at a level within the puck 202 that is below the level of the wafer grid 206. The process kit grid 350—or at least an outer annular portion thereof—underlies the process kit collar 214 and therefore can capacitively couple RF power to the collar 214. The wafer grid 206 completely underlies the wafer 204 so that substantially all RF power applied to the wafer grid 206 is capacitively coupled to the wafer 204. The two grids 206, 350 are electrically insulated from one another, and therefore provide a way of adjusting the different levels of RF power coupled to the wafer 204 and the process kit collar 214.

A process kit grid RF feed conductor 352 extends through the center insulator 242 and through the puck 202 so that its top end contacts the process kit grid 350. The bottom end of the process kit grid RF feed conductor 352 is coupled to the output of the bias RF match circuit 234. An optional process kit grid variable impedance element 271 may be interposed between the output of the bias RF match circuit 234 and the feed conductor 352. Only one of the two variable impedance elements 271, 272 of FIG. 3 is required to apportion RF bias power between the two grids 206, 350, although the combination of both of them affords a greater range of adjustment.

The embodiment of FIG. 3 may further include the same type of elements for controlling the temperature of the process kit collar 214. Specifically, a thermally conductive gas may be circulated beneath the process kit collar 214, and the process kit collar 214 may be electrostatically clamped to the puck 202 with a force that is variable to vary or control thermal conductivity at the collar-puck interface, for temperature control of the collar 214. The shoulder 202b of the puck 202 defines an outer annular puck surface 202c on which the process kit collar 214 rests. Channels 311 are formed in the outer annular puck surface 202c for thermally conductive gas (e.g., Helium) circulation. The channels 311 are completely enclosed when the collar 214 is clamped to the puck outer annular surface 202c. The collar 214 is electrostatically clamped or chucked to the puck outer annular surface 202c by the ESC voltage supply 298 whose output is coupled to the process kit grid feed conductor 352 in the embodiment of FIG. 3. The optional isolation filter 299 may be interposed between the ESC voltage supply 298 and the grid feed conductor 352. Fine control of the temperature of the collar 214 may be realized by the system controller 280 varying the output voltage of the ESC supply 298, which varies the collar-to-puck thermal conductivity by varying the electrostatic clamping force on the collar 214.

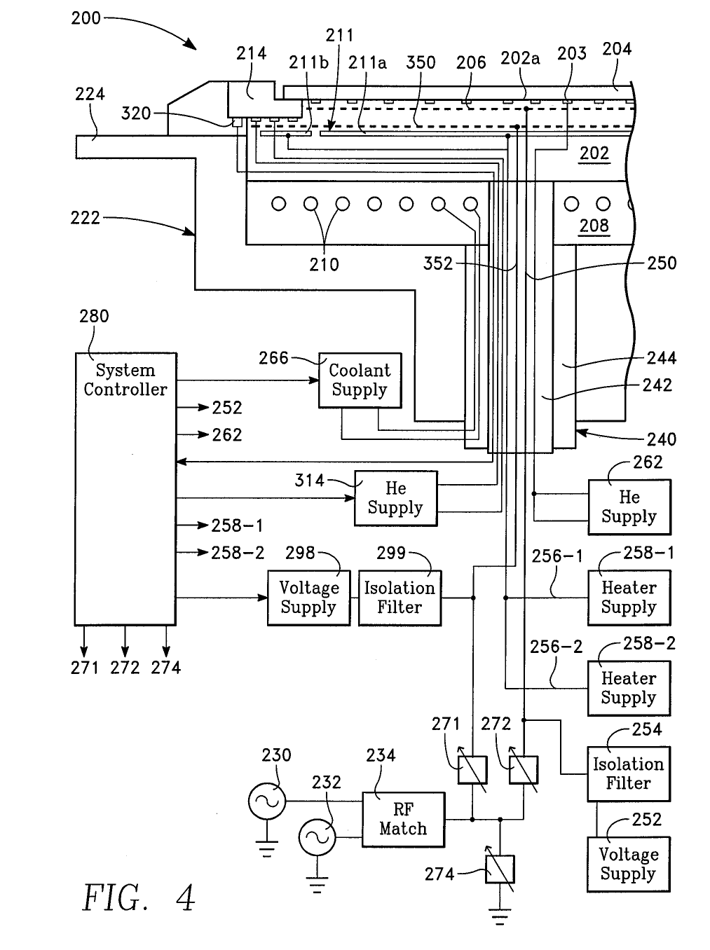

The embodiment of FIG. 3 may be modified by eliminating the cathode insulator 221 so that the metal plate 208 is grounded to the cathode ground housing 222, as depicted in FIG. 4.

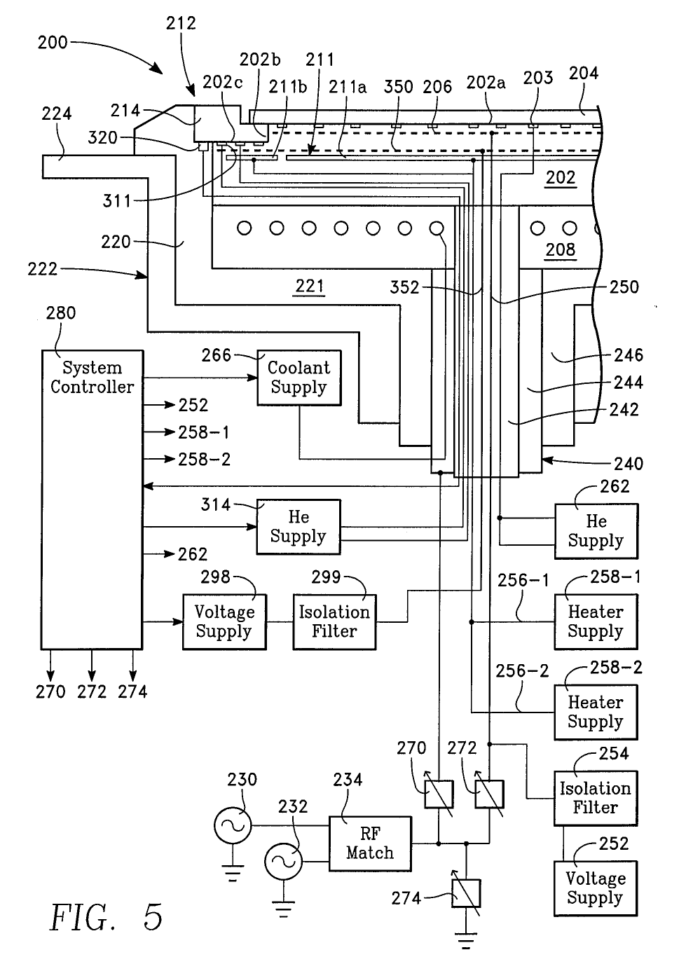

The features described above with reference to FIG. 3 for thermally controlling the collar 214 may be incorporated into the embodiment of FIG. 1B and operate in the manner described above with reference to FIG. 3. Such an enhancement of the embodiment of FIG. 1B is depicted in FIG. 5. The embodiment of FIG. 5 is the same as that of FIG. 1B except that certain thermal control features, described above with reference to FIG. 3, have been added. In FIG. 5, the process kit spacer ring 216 has been eliminated (although in other implementations it may be retained), so that the puck 202 may extend beneath the process kit collar 214, as shown in FIG. 5. A shoulder 202b in the puck 202 defines an annular puck surface 202c underlying and contacting the bottom surface of the collar 214. Gas flow channels 311 are formed in the annular puck surface 202c and coupled to an independent supply 314 of a thermally conductive gas (e.g., helium). The outer heating element 211b is located directly beneath the collar 214, as depicted in FIG. 5. A temperature sensor 320 adjacent the process kit collar 214 is coupled to the system controller 280. Optionally, a second conductive grid 350 may be embedded in the puck 202 beneath the collar 214 and employed to electrostatically clamp or chuck the collar 214 onto the annular puck surface 202c. In the embodiment of FIG. 5, the second conductive grid 350 is coupled to an ESC chucking voltage supply 298 through an RF isolation filter 299. The voltage of the supply 298 is controlled by the system controller 280 to vary the clamping force on the collar 214, and thereby vary the collar temperature.

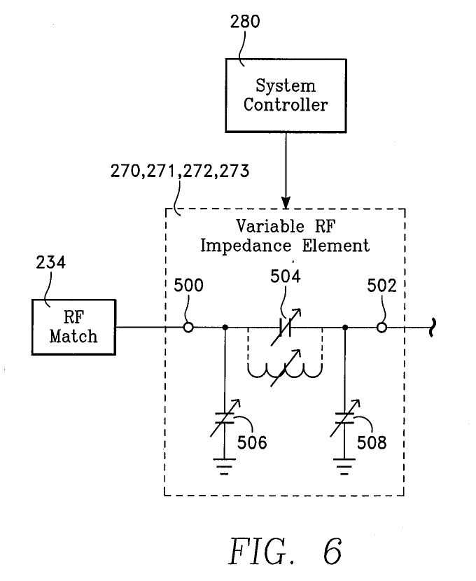

The variable impedance elements 270, 271, 272, 273 described above with reference to the embodiments of FIGS. 1-5 are employed for apportioning RF bias power between the process kit and the workpiece. While any suitable variable reactance circuit may be used to implement each of the variable impedance elements 270, 271, 272, 273, FIG. 6 is a simplified schematic diagram of one example of an implementation of one of the variable impedance elements 270, 271, 272 or 273. The variable impedance element of FIG. 6 consists of an input terminal 500 that is coupled to the output of the bias RF impedance match circuit 234 and an output terminal 502. Between the input and output terminals 500, 502 is connected a series variable capacitor 504. Optionally an input parallel capacitor 506 is connected between the input terminal 500 and RF ground and an output parallel capacitor 508 is connected between the output terminal 502 and RF ground. All or any one of the capacitors 504, 506, 508 may be a variable capacitor. In an alternative embodiment, any one of the capacitors 504, 506, 508 may be replaced by a suitable inductor that may be variable.

While the foregoing is directed to embodiments of the present invention, other and further embodiments of the invention may be devised without departing from the basic scope thereof, and the scope thereof is determined by the claims that follow.

What is claimed is:

1. An RF bias workpiece support system for use in a plasma reactor chamber, comprising:
a puck having a workpiece support surface for supporting a workpiece;
a workpiece electrode embedded in said puck, said workpiece electrode underlying and generally parallel to said workpiece support surface;
a metal plate underlying said puck;
an annular process kit collar surrounding a peripheral edge of said workpiece support surface;
a process kit electrode element underlying said process kit collar;
an RF plasma bias power supply coupled to said workpiece electrode and to said process kit electrode element;
a variable RF impedance element comprising a reactive element having a variable reactance, said variable RF impedance element being coupled between said RF plasma power supply and one of: (a) said workpiece electrode, (b) said process kit electrode; and
a system controller connected to a control input of said variable RF impedance element whereby to govern said variable reactance of said reactive element of said variable RF impedance element.

2. The system of claim 1 wherein:
said metal plate comprises a central portion underlying said workpiece support surface and an outer portion underlying said process kit collar;
said process kit electrode element comprises said outer portion of said metal plate, wherein said metal plate comprises an RF-driven cathode.

3. The system of claim 1 further comprising:
an annular insulator layer surrounding said puck and said metal plate;
an annular process kit conductor in said insulator layer and extending axially through said annular insulator layer, said annular conductor comprising a kit support surface underlying and contacting said process kit collar;
and wherein said process kit electrode element comprises said annular conductor.

4. The system of claim 1 further comprising an embedded planar process kit electrode in said puck and separate from and generally parallel with said workpiece electrode, said embedded process kit electrode comprising an annular outer portion underlying said process kit collar, and wherein:
said process kit electrode element comprises said annular outer portion of said embedded process kit electrode.

5. The system of claim 4 wherein said metal plate is grounded.

6. The system of claim 1 wherein said variable RF impedance element is connected between said bias RF power supply and said workpiece electrode.

7. The system of claim 6 further comprising a second variable RF impedance element connected between said bias RF power supply and said process kit electrode element, said system controller being connected to a control input of said second variable RF impedance element whereby to govern an impedance of said second variable RF impedance element.

8. The system of claim 1 further comprising a cathode ground variable impedance element comprising an input terminal and a ground terminal, said input terminal being coupled to said workpiece electrode and to said process kit electrode element, said ground terminal being connected to an RF ground potential.

9. The system of claim 1 further comprising:
a first electrostatic chucking voltage supply coupled to said workpiece electrode; and
a second electrostatic chucking voltage supply coupled to said process kit electrode element, said system controller being coupled to said first and second electrostatic chucking voltage supplies whereby to separately govern clamping forces applied to a workpiece on said workpiece support surface and to said process kit collar.

10. The system of claim 2 wherein said puck comprises a central puck portion underlying said workpiece support surface and an outer puck portion underlying said process kit collar, said outer puck portion having a collar support surface underlying said collar, said system further comprising:
fluid coolant flow passages in said metal plate;
gas flow channels in said collar support surface.

11. The system of claim 10 further comprising:
a process kit collar electrostatic chucking electrode underlying said collar;
a first electrostatic chucking voltage supply coupled to said workpiece electrode;
a second electrostatic chucking voltage supply coupled to said process kit collar electrostatic chucking electrode, said system controller being connected to govern separate output voltages of said first and second electrostatic chucking voltage supplies.

12. The system of claim 3 further comprising:
fluid coolant flow passages in said annular process kit conductor;
gas flow channels in said kit support surface of said annular conductor.

13. The system of claim 12 further comprising:
a first electrostatic chucking voltage supply coupled to said workpiece electrode;
a second electrostatic chucking voltage supply coupled to said process kit annular conductor; and
wherein said system controller is connected to separately govern output voltages of each of said first and second electrostatic chucking voltage supplies.

14. The system of claim 4 further comprising:
a first electrostatic chucking voltage supply coupled to said workpiece electrode;
a second electrostatic chucking voltage supply coupled to said embedded process kit electrode; and
wherein said system controller is connected to separately govern output voltages of each of said first and second electrostatic chucking voltage supplies.

15. The system of claim 1 wherein said puck comprises a bottom surface on a side opposite said workpiece support surface, said system further comprising:
an elongate center insulator extending axially along an axis of symmetry of said puck from said bottom surface of said puck and through said metal plate and terminated at a bottom end thereof;
an annular cathode feed conductor surrounding and extending coaxially with said center insulator from a bottom surface of said metal plate and terminated at a bottom end thereof; and
a workpiece electrode feed conductor extending through said center insulator and through said puck, said workpiece electrode feed conductor having a top end connected to said workpiece electrode and a bottom end extending through the bottom end of said center insulator to provide a current path between said bias RF power supply and said workpiece electrode.

16. The system of claim 15 further comprising:
a process kit electrode feed conductor extending axially through said center insulator;
a first electrostatic chucking voltage supply coupled to said workpiece electrode feed conductor at a bottom end thereof;
a second electrostatic chucking voltage supply coupled to said process kit electrode feed conductor at a bottom end thereof; and
said system controller being connected to govern separate output voltages of said first and second electrostatic chucking voltage supplies.

17. The system of claim 16 wherein said process kit electrode portion comprises an outer portion of said metal plate and said process kit electrode feed conductor comprises said annular cathode feed conductor.

18. The system of claim 16 further comprising:
first gas flow channels in said workpiece support surface;
second gas flow channels beneath said process kit collar;
a first supply of a conductive gas and first gas flow conduits axially extending through said annular cathode feed conductor between said first supply and said first gas flow channels; and
a second supply of a conductive gas and second gas flow conduits axially extending through said annular cathode feed conductor between said second supply and said second gas flow channels.
